(19) United States
(12) Patent Application Publication
(10) Pub. No.: US 2011/0036545 A1
(43) Pub. Date: Feb. 17, 2011

(54) HIGH-PERFORMANCE HEAT SINK

(76) Inventor: Tsung-Hsien Huang, I-Lan Hsien (TW)

Correspondence Address: PAI PATENT & TRADEMARK LAW FIRM, 1001 FOURTH AVENUE, SUITE 3200, SEATTLE, WA, 98154, US

(21) Appl. No.: 12/539,916

(22) Filed: Aug. 12, 2009

(51) Int. Cl. H05K 7/20; F28D 15/04; F28F 7/00

(52) U.S. Cl. 165/104.26; 165/185

(57) ABSTRACT

A high-performance heat sink includes a set of first radiation fins each having an abutment portion, two radiation fins extending from two lateral sides of the abutment portion, and upright pins extending from each radiation fin portion; a fastener that fastens the abutment portions of the first radiation fins together such that the radiation fins are radially extended out; second radiation fins fastened to the upright pins of the first radiation fins and arranged at different elevations; and thermal pipes fastened to the bottom side of the abutment portions of the first radiation fins, each thermal pipe having two distal ends respectively fastened to the two distal ends of each second radiation fin.

### BACKGROUND OF THE INVENTION

(a) Field of the Invention

The present invention relates to heat dissipation apparatus and more particularly to a high-performance heat sink that enhances dissipation of heat.

(b) Description of the Prior Art

Heat sink is an important heat dissipation device widely used in the electronic industry for dissipation of waste heat from an electronic member. FIG. 1 shows a heat sink according to the prior art. According to this design, the heat sink comprises a solid metal bottom block 10 and a plurality of metal radiation fins 20 located on the top side of the solid metal bottom block 10. In application, the solid metal bottom block 10 is attached to the surface of the electronic device 30 for transferring waste heat from the electronic device 30 to the radiation fins 20 for heat exchange with cold air to expel waste heat. However, in arranging multiple radiation fins 20 to the solid metal bottom block 10, one must consider the fixation stability and precision and heat transferring efficiency. In consequence, the cost of the design, fabrication and assembly of the heat sink is relatively high. In order to save the cost, the radiation fins may be directly secured together to form a heat sink.

FIG. 2 shows another design of heat sink according to the prior art. According to this design, the heat sink is comprised of a plurality of radiation fins 40. Each radiation fin 40 has an abutment portion 401 and a radiation fin portion 402 extending from one end of the abutment portion 401 at a predetermined angle. The abutment portions 401 of the radiation fins 40 are attached together, forming a base 403 for direct contact with the surface of the electronic device 30 to be cooled down. Because the base 403 is not a solid block, gaps may be left in between the base 403 and the surface of the electronic device 30, lowering the heat transfer efficiency of the radiation fins 40 and resulting in low heat dissipation performance.

### SUMMARY OF THE INVENTION

The present invention has been accomplished under the circumstances in view. It is one object of the present invention to provide a high-performance heat sink, which increases the heat dissipation surface area and enhances the heat dissipation performance. It is achieved by means of joining a plurality of first radiation fins and a plurality of second radiation fins together so that abutment portions of the first radiation fins are attached to the electronic device to be cooled for transferring heat from the electronic device to radiation fin portions of the first radiation fins and the second radiation fins.

In another embodiment of the present invention, thermal pipes are joined to the first radiation fins and extended to the second radiation fins, thus enhancing heat dissipation performance.

To achieve these and other objects of the present invention, a heat sink comprises a plurality of first radiation fins, a fastener, a plurality of second radiation fins, and at least one thermal pipe. Each first radiation fin has an abutment portion, a radiation fin portion extending from at least one of two lateral sides of the abutment portion, and upright pins extending from each radiation fin portion. The fastener fastens the abutment portions of the first radiation fins together such that the radiation fins are radially extended out. The second radiation fins are fastened to the upright pins of the first radiation fins and arranged at different elevations and kept apart from each other. Each thermal pipe is fastened to the bottom side of the abutment portions of the first radiation fins, having two distal ends thereof respectively fastened to a respective mounting through hole on each of the two distal ends of each second radiation fin.

In application, the abutment portions of the first radiation fins and the middle part of each thermal pipe are attached to the surface of the electronic device so that some of the waste heat released by the electronic device is transferred from the electronic device through the abutment portions to the radiation fin portions of the first radiation fins and to the second radiation fins via the upright pins, and then dissipated into the atmosphere rapidly. At the same time, the thermal pipes transfer a part of the waste heat from the electronic device to the second radiation fins for heat exchange with the surrounding air.

### BRIEF DESCRIPTION OF THE DRAWINGS

FIG. 1 is a schematic drawing showing a heat sink formed of a base block and a set of radiation fins according to the prior art.

FIG. 2 is a schematic drawing showing another structure of heat sink formed of a set of radiation fins according to the prior art.

FIG. 3 is an elevational view of a high-performance heat sink in accordance with the present invention.

FIG. 4 is an exploded view of the high-performance heat sink in accordance with the present invention.

FIG. 5 is an exploded view of an alternate form of the high-performance heat sink with an alternate form of the radiation fin fastener in accordance with the present invention.

FIG. 6 is an exploded view of a part of the high-performance heat sink in accordance with the present invention, showing the structure of the first radiation fins.

FIG. 7 is an exploded view of a part of high-performance heat sink in accordance with the present invention, showing the structure of the second radiation fins.

FIG. 8 is an elevational view of another alternate form of the high-performance heat sink in accordance with the present invention, showing thermal pipes installed in the first radiation fins and the second radiation fins.

FIG. 9 is an exploded view of FIG. 8.

FIG.10 is a top view of FIG. 8.

FIG. 11 is a front view of FIG. 8

FIG. 12 is a sectional view of FIG. 8.

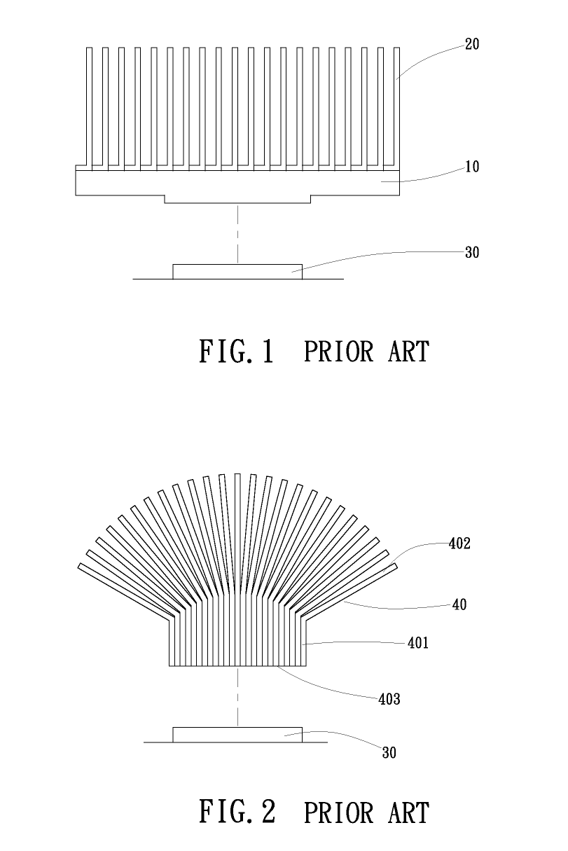

### DETAILED DESCRIPTION OF THE PREFERRED EMBODIMENTS

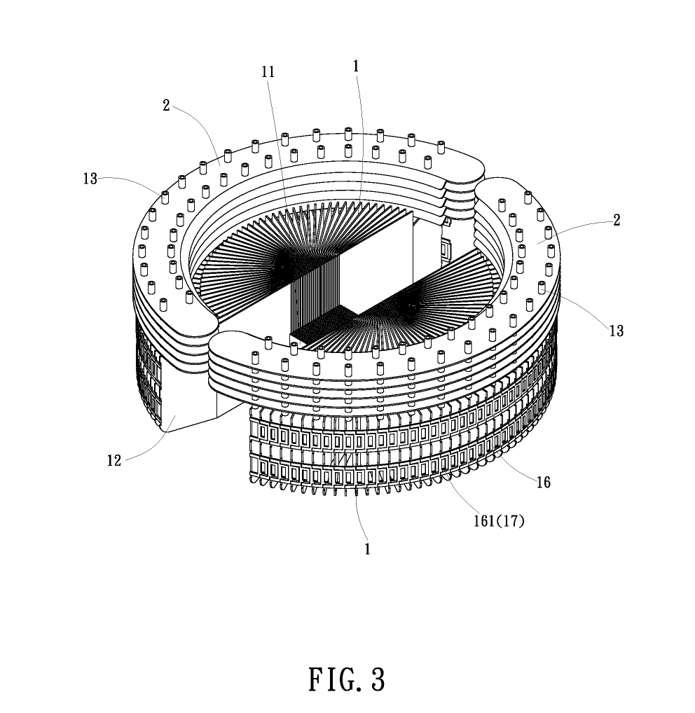

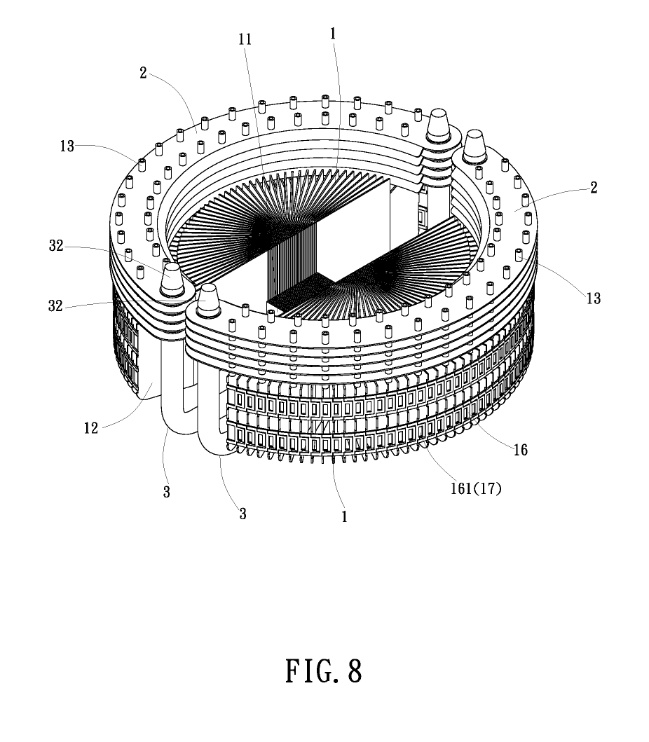

As illustrated in FIG. 3, a high-performance heat sink in accordance with the present invention comprises a plurality of first radiation fins 1 and a plurality of second radiation fins 2. Further, the heat sink may optionally include one or more thermal pipes 3 attached to the first and second radiation fins, as shown in FIG. 8.

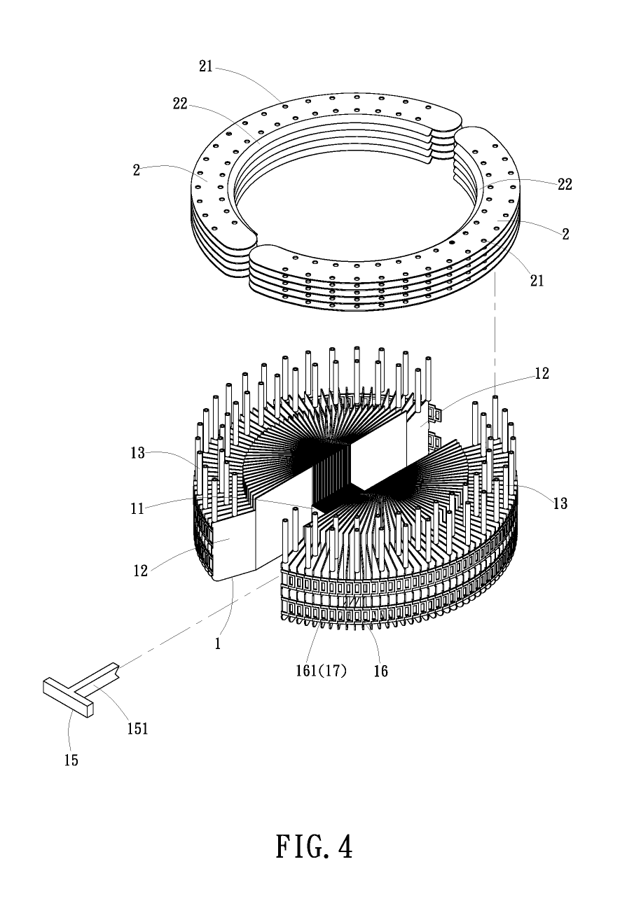

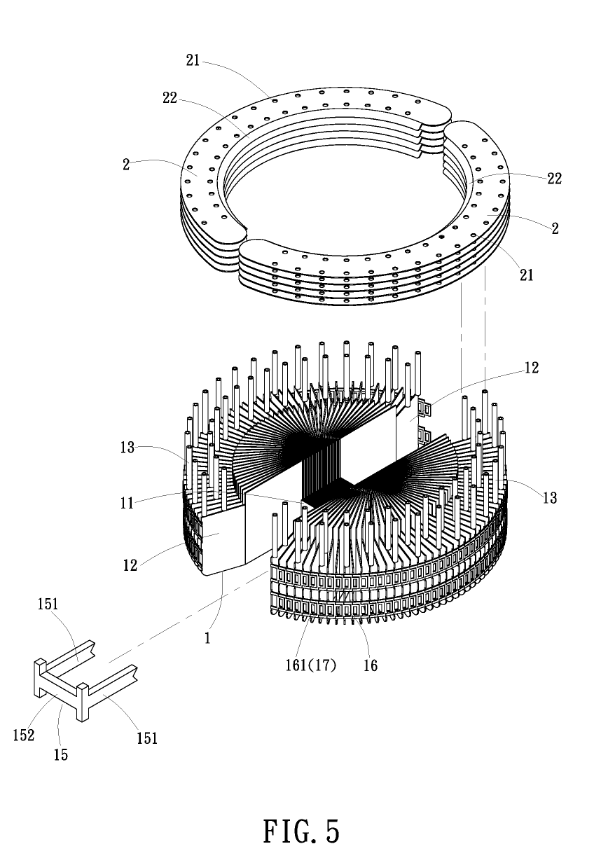

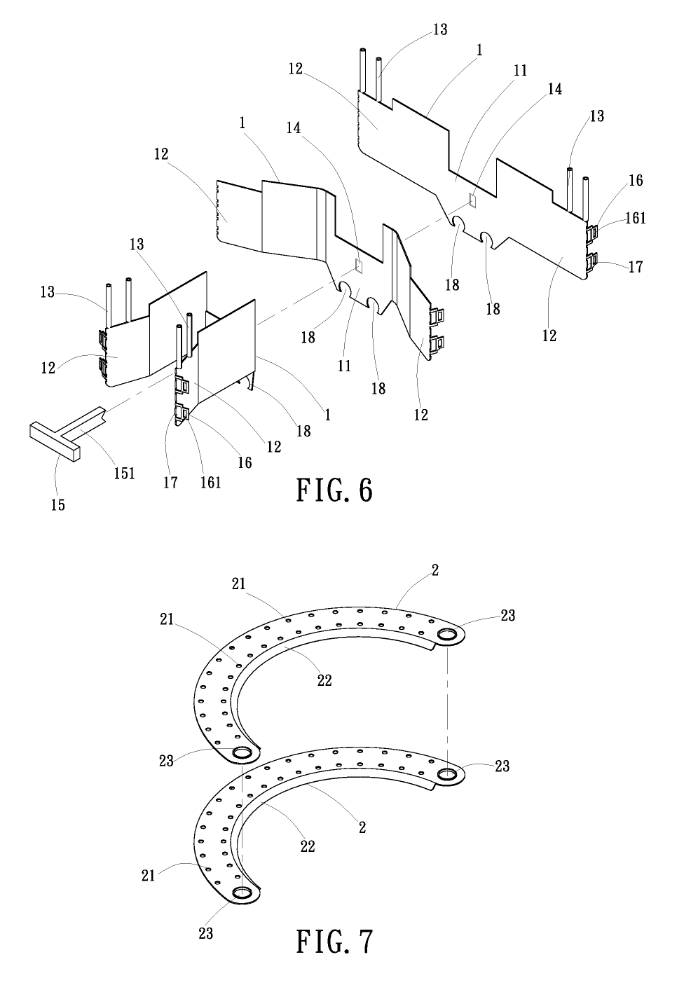

Each first radiation fin 1, as shown in FIG. 4 and FIG. 6, has an abutment portion 11 in the shape of, for example, a flat sheet, and one radiation fin portion 12 at one side or each of two opposite sides of the abutment portion 11. When the abutment portions 11 of the first radiation fins 1 are fastened together, the radiation fin portions 12 extend radially such that the first radiation fins 1 define a sector-like configuration. A predetermined number of the first radiation fins 1 each further have at least one upright pin 13 vertically upwardly extending from the top side for the mounting of the second radiation fins 2. Further, the abutment portion 11 has at least one mounting through hole 14, and a radiation fin fastener 15 is used to fasten the abutment portions 11 of the first radiation fins 1. According to the embodiment shown in FIGS. 4 and 6, each abutment portion 11 has one single mounting through hole 14; the radiation fin fastener 15 is a T-shaped rivet 151. After the T-shaped rivet 151 is inserted through the mounting through holes 14 of the abutment portions 11 of the first radiation fins 1, the plain end of the T-shaped rivet 151 is hammered down to fixedly secure the abutment portions 11 of the first radiation fins 1 together. According to the embodiment shown in FIG, 5, each abutment portion 11 has two mounting through holes 14; the radiation fin fastener 15 is comprised of two T-shaped rivets 151 and a transverse bar 152 connected between the heads of the T-shaped rivets 151. After the two T-shaped rivets 151 of the radiation fin fastener 15 are inserted through the two mounting through holes 14 of the abutment portion 11 of each of the first radiation fins 1, the plain end of each T-shaped rivet 151 of the radiation fin fastener 15 is hammered down to fixedly secure the abutment portions 11 of the first radiation fins 1 together. Further, as shown in FIG. 6, each radiation fin portion 12 has at least one eye lug 16 and at least one hook lug 17. Each eye lug 16 defines therein a hook hole 161. After the abutment portions 11 of the first radiation fins 1 are affixed together by the radiation fin fastener 15, the hook lug 17 of each first radiation fin 1 is fastened to the hook hole 161 of one respective eye lug 16 of an adjacent first radiation fin 1, thus enhancing the connection stability of the first radiation fins 1.

The second radiation fins 2, as shown in FIG. 4 and FIG. 7, are arranged in two stacks, each radiation fin 2 having a plurality of mounting through holes 21 respectively fastened to the upright pins 13 of the first radiation fins 1 for supporting the two stacks of the second radiation fins 2 on the first radiation fins 1. Further, the second radiation fins 2 of each stack are vertically spaced from one another at a predetermined gap. Each second radiation fin 2 further has a wind guide flange 22 downwardly extending from the inner side thereof for guiding the flow of a stream of air induced, say, by an electric fan.

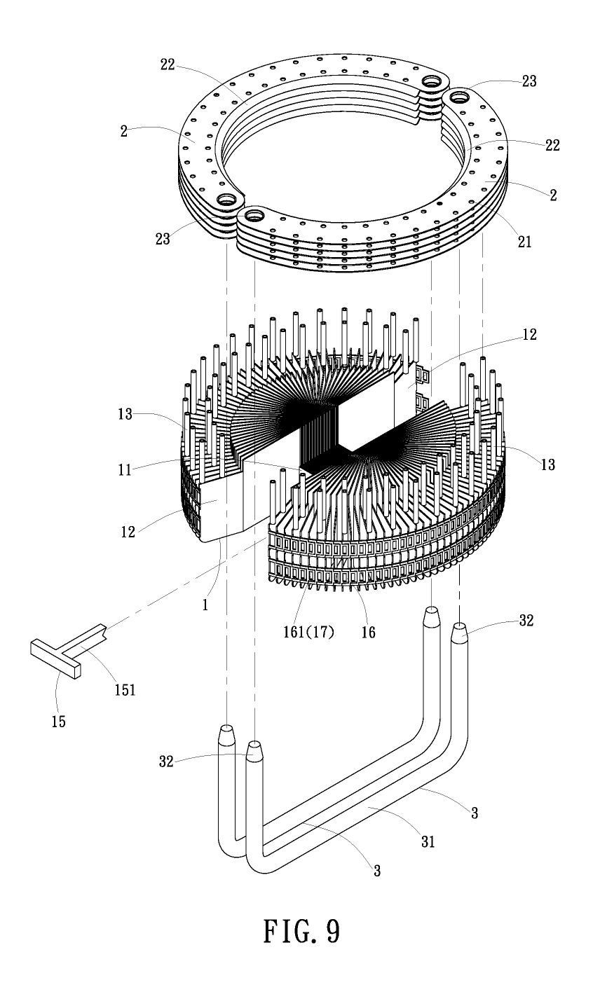

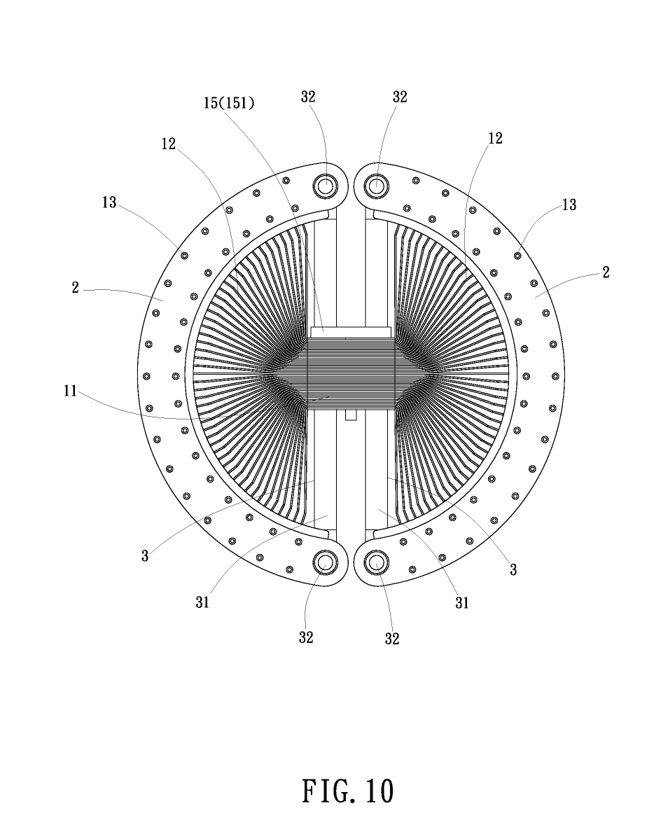

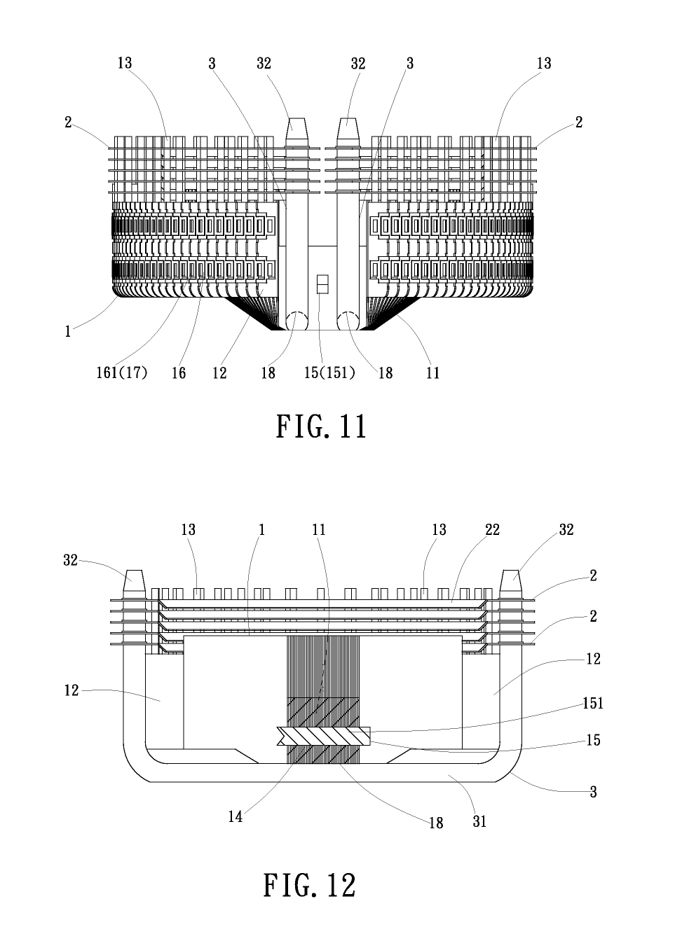

Referring to FIG. 8 and FIG. 9, at least one thermal pipe 3 may be attached to the heat sink to enhance the heat dissipation performance. As shown in FIG. 6 and FIG. 7, each first radiation fin 1 has at least one semicircular bottom notch 18 on the bottom side of the abutment portion 11; the second radiation fins 2 are semicircularly shaped, each having a plughole 23 on each of the two distal ends thereof; the thermal pipes 3, as shown in FIG. 9, are U-pipes having a middle heat absorbing portion 31 fastened to the semicircular bottom notches 18 on the bottom side of the first radiation fins 1 (see FIG. 10 through FIG. 12) and two heat dissipation portions 32 respectively inserted through and fastened to the plugholes 23 of the second radiation fins 2.

In application of the high-performance heat sink to dissipate heat from an electronic device, the bottom edge of the abutment portion 11 of each of the first radiation fins 1 and the middle heat absorbing portions 31 of the thermal pipes 3 are attached to the surface of the electronic device (such as, CPU). During the operation of the electronic device, waste heat is released. A part of the waste heat released by the electronic device is transferred through the abutment portions 11 to the radiation fin portions 12 of the first radiation fins 1 and to the second radiation fins 2 via the upright pins 13 and then dissipated into the atmosphere. Further, the invention has the aforesaid thermal pipes 3 joined to the heat sink so that a substantial part of the waste heat released by the electronic device is absorbed by the middle heat absorbing portions 31 of the thermal pipes 3 and rapidly transferred through the heat dissipation portions 32 respectively fastened through the plugholes 23 of the second radiation fins 2 for dissipation into the atmosphere. By means of heat change between the radiation fin portions 12 of the first radiation fins 1 and the second radiation fins 2 of the heat sink with the outside cooling air, the invention enhances heat dissipation performance. Further, the arrangement of the two stacks of the second radiation fins 2 on the top side of the first radiation fins 1 relatively increase the total heat dissipation surface area. Further, by means of joining the thermal pipes 3 to the semicircular bottom notches 18 on the bottom side of each of the first radiation fins 1, the heat sink can be kept in close contact with the surface of a heat source to transfer heat from the heat source efficiently for quick dissipation.

A prototype of high-performance heat sink has been constructed with the features of FIGS. 3˜12. The high-performance heat sink functions effectively to provide all of the features disclosed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A heat sink, comprising a plurality of first radiation fins and a plurality of second radiation fins, each said first radiation fin having an abutment portion and a radiation fin portion extending from at least one of two opposite lateral sides of the abutment portion, the abutment portions of said first radiation fins being affixed together to keep the radiation fin portions of said first radiation fins spaced from one another, wherein each of a predetermined number of said first radiation fins has at least one upright pin vertically upwardly extending from a top side of each radiation fin portion thereof; the second radiation fins are supported above the radiation fin portions of said first radiation fins at different elevations and kept apart from one another at a predetermined gap; and each said second radiation fin has a plurality of mounting through holes fastened to the upright pins of said first radiation fins for allowing transfer of heat from said first radiation fins to said second radiation fins.

2. The heat sink as claimed in claim 1, further comprising at least one thermal pipe fastened to a bottom side of said first radiation fins, each said thermal pipe having two distal ends respectively fastened to said second radiation fins.

3. The heat sink as claimed in claim 2, wherein each said first radiation fin has at least one bottom notch on a bottom edge of the abutment portion thereof for receiving said at least one thermal pipe; said second radiation fins are semicircularly shaped, each having a plughole on each of two distal ends thereof; each said thermal pipe has the two distal ends thereof respectively inserted through and fastened to the plugholes of said second radiation fins.

4. The heat sink as claimed in claim 3, wherein each said second radiation fin has a wind guide flange downwardly extending from an inner side thereof.

5. The heat sink as claimed in claim 1, wherein each said first radiation fin has two radiation fin portions respectively symmetrically extending from two opposite lateral sides of the abutment portion thereof.

6. The heat sink as claimed in claim 1, wherein the radiation fin portions of said first radiation fins define a sector-like configuration when the abutment portions of said first radiation fins are fastened together.

7. The heat sink as claimed in claim 1, wherein each said first radiation fin has at least one hook lug and at least one eye lug extending from one lateral side of each radiation fin portion opposite to the abutment portion thereof, the hook lug of each said first radiation fin being fastened to one eye lug of another said first radiation fin.

8. The heat sink as claimed in claim 1, further comprising a fastener that fastens the abutment portions of said first radiation fins together.

9. The heat sink as claimed in claim 8, wherein each said first radiation fin has a mounting through hole cut through the abutment portion thereof; and said fastener is a T-shaped rivet inserted through and fastened to the mounting through hole of each said first radiation fin.

10. The heat sink as claimed in claim 8, wherein each said first radiation fin has two mounting through holes cut through the abutment portion thereof; and said fastener comprises two T-shaped rivets respectively inserted through and fastened to the two mounting through holes of each said first radiation fin, and a transverse bar connected between one end of each of the two T-shaped rivets.
